(19) United States
(12) Patent Application Publication
(10) Pub. No.: US 2026/0101812 A1
(43) Pub. Date: Apr. 9, 2026

(54) MICROSTRUCTURED IC CHIP

(71) Applicant: Robert Bosch GmbH, Stuttgart (DE)

(72) Inventors: Johannes Boy, Moessingen (DE); Ali Tavassolizadeh, Kirchentellinsfurt (DE); Andreas Scheurle, Leonberg (DE); Christoph Kaiser, Reutlingen (DE); Martin Rambach, Pliezhausen (DE); Volker Schmitz, Pfullingen (DE)

(21) Appl. No.: 19/344,935

(22) Filed: Sep. 30, 2025

(30) Foreign Application Priority Data
Oct. 8, 2024 (DE) 10 2024 209 807.8

(51) Int. Cl. H01L 23/10; H01L 23/00; H01L 25/065

(52) U.S. Cl. CPC H10W 76/60; H10W 90/00; H10W 72/641; H10W 90/762

(57) ABSTRACT

An IC chip. The IC chip has an IC substrate, at least one IC functional layer on the substrate, and an etching hole that penetrates the IC functional layer from an outer side through to the substrate. A metal seal is arranged between a region of the IC functional layer and the etching hole.

### CROSS REFERENCE

The present application claims the benefit under 35 U.S.C. § 119 of Germany Patent Application No. DE 10 2024 209 807.8 filed on Oct. 8, 2024, which is expressly incorporated herein by reference in its entirety.

### FIELD

The present invention is based on an IC chip that has an IC substrate and at least one IC functional layer. At least one etching hole of any geometry is present in the IC functional layer.

### BACKGROUND INFORMATION

IC chips are typically constructed from a sequence of different functional layers, for example silicon oxides or silicon nitrides. The choice of material and the method of manufacturing the IC functional layer, as well as the underlying material, influence the crystalline properties of the functional layer. The IC functional layer has a changed crystal structure due to a change in the intrinsic lattice constant. Although lattice defects partially relax these distortions, an intrinsic stress always remains in the layer. This intrinsic stress can also vary during further manufacturing due to the influence of temperature or the application of additional functional layers. With subsequent large-area and uniform structuring of the IC functional layer, the intrinsic stress of the layer can relax. If the IC functional layer is locally structured, this structuring can act as a weak point or defect through which the layer stress is reduced in an uncontrolled manner. This can cause defects, delamination and cracks, which spread also into deeper layers and cause irreparable damage to the component.

### SUMMARY

An object of the present invention is to integrate a sealing and mechanically or crystallographically decoupling structure into IC functional layers in order to prevent the propagation of defects, delamination or cracks in the vicinity of local structuring.

The present invention is based on an IC chip that has an IC substrate and at least one functional layer. At least one etching hole of any geometry is present in the functional layer.

According to the present invention, the functional layer has a metal-filled structure that functions as a seal, in particular as a sealing ring, and protects local structuring from the formation of defects, delamination and cracks. The metal sealing ring can have additional functions and, for example, function as an electrical contact between the IC chip and the MEMS chip, which is connected to the IC chip by a bonding process, or as a particle barrier.

The present invention also provides a metal sealing ring that functions as a vertical barrier against the propagation of layer stress-induced defects in IC functional layers. This makes it possible to create etching holes of any size, shape and position. The metal sealing ring can additionally serve as an electrical contact or as a barrier to particles.

Advantageously, the present invention makes it possible to prevent defects, delamination and cracks originating from local structuring by means of a metal-filled structure (metal sealing ring) or to reduce layer stress. Should such defects occur in the structuring, they can only spread to this sealing ring and are prevented or eliminated there. The metal sealing ring is particularly advantageous when the layer undergoes further manufacturing processes in which layer stress is induced again through temperature or additional functional layers.

An advantageous embodiment of the present invention provides that the metal sealing ring is located in the uppermost level of the IC chip and is electrically conductively connected to relevant electrical potentials of the IC chip. In this way, an electrical contact, for example for the ground potential of the IC chip, can be manufactured on the surface.

An advantageous embodiment of the present invention provides that the metal sealing ring is not flush with the IC functional layer, but rather has a raised topography. If the IC chip is connected to a MEMS chip having a cavity by means of a bonding process, the metal sealing ring can advantageously be used to locally set a defined distance between the surface of the MEMS chip and the surface of the metal sealing ring. For example, this distance can be minimized to create regions in the cavity between which gas exchange can take place, but no exchange of particles greater than the distance between the sealing ring and the surface of the MEMS chip. If the etching hole enclosed by the metal sealing ring serves, for example, as an access hole for a trench that runs through the substrate of the IC chip, allows gas access into the cavity and is subsequently closed again using a laser fusion process, the metal sealing ring having a raised topography can also serve as a bottleneck between the IC and MEMS chip. This allows gas exchange between the external atmosphere and the cavity of the MEMS chip before the trench is closed and prevents particles from penetrating the MEMS chip beyond the etching hole through the metal sealing ring.

Further advantageous embodiments of the present invention are disclosed herein.

### BRIEF DESCRIPTION OF THE DRAWINGS

FIGS. 1A and 1B schematically show a first and a second exemplary embodiment of an IC chip according to the present invention having a metal sealing ring enclosing an etching hole.

FIGS. 2A and 2B schematically show a third and fourth exemplary embodiment of an IC chip according to the present invention having a metal sealing ring that contacts an underlying electrically conductive layer.

FIG. 3 schematically shows a fifth exemplary embodiment of an IC chip according to the present invention having a metal sealing ring with a flange.

FIGS. 4A-4D schematically show, in further exemplary embodiments, an IC chip according to the present invention having a metal sealing ring that, in different ways, penetrates an IC functional layer system comprising a plurality of layers, in whole or in part.

### DETAILED DESCRIPTION OF EXAMPLE EMBODIMENTS

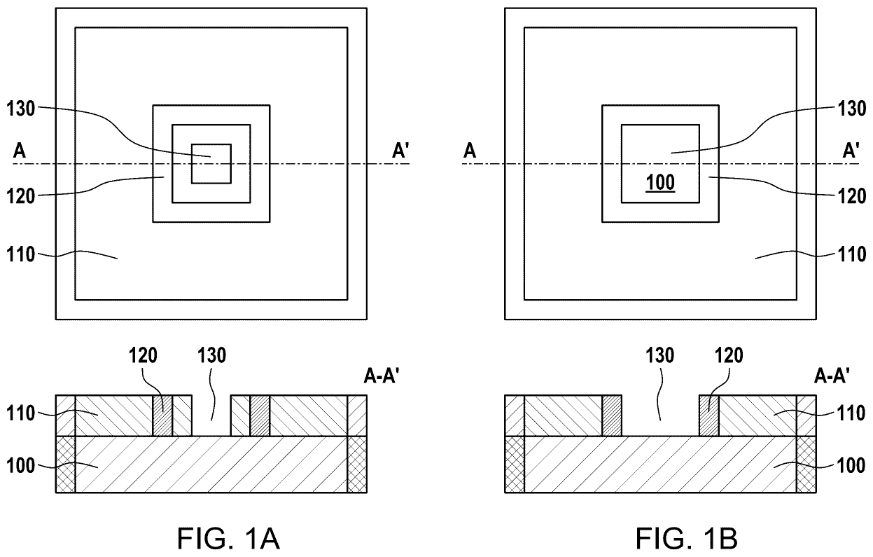

FIGS. 1A and 1B schematically show a first and a second exemplary embodiment of an IC chip according to the present invention having a metal sealing ring enclosing an etching hole.

FIG. 1A is a schematic plan view and section of the IC chip according to them present invention in a first exemplary embodiment. Shown is an IC chip having a substrate 100, at least one IC functional layer 110, and a rectangular etching hole 130. The etching hole is surrounded directly by a partial region of the IC functional layer and indirectly by a metal sealing ring 120, which is also rectangular.

FIG. 1B is a schematic plan view and section of the IC chip according to the present invention in a second exemplary embodiment. Shown is an IC chip having a substrate 100, at least one IC functional layer 110, and a rectangular etching hole 130. The etching hole is surrounded directly by a metal sealing ring 120, which is also rectangular.

The IC chip is, for example, an application-specific integrated circuit (ASIC). The layer system of this integrated circuit, including the metal layers, is not shown in detail here; instead, it is consolidated into the IC functional layer and the IC chip. The etching hole can have a rectangular or square outline, as shown here, but can also take on any other possible shape. The metal sealing ring can completely or partially enclose the etching hole in any shape and can be filled with aluminum, for example.

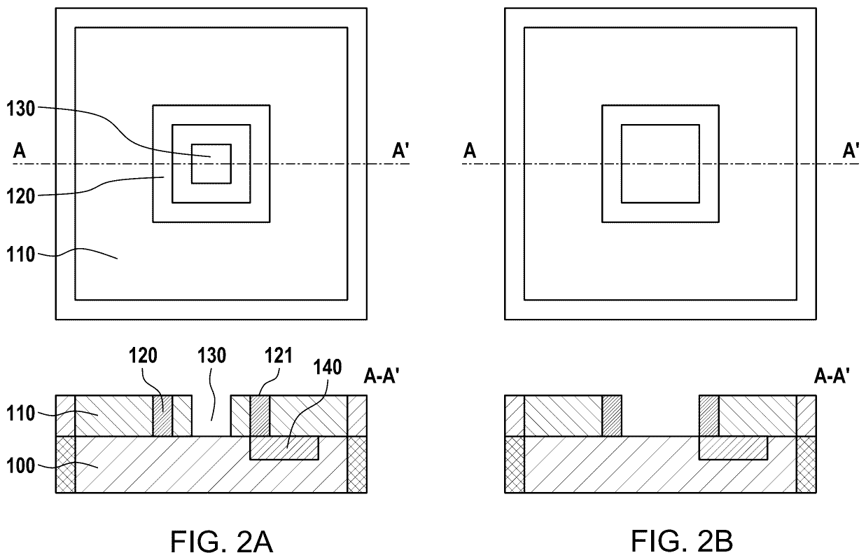

FIGS. 2A and 2B schematically show a third and fourth exemplary embodiment of an IC chip according to the present invention having a metal sealing ring that contacts an underlying electrically conductive layer.

FIG. 2A is a schematic plan view and section of the IC chip according to the present invention in a third exemplary embodiment. Shown is an IC chip having a substrate 100, at least one IC functional layer 110, and a rectangular etching hole 130. The etching hole is surrounded directly by a partial region of the IC functional layer and indirectly by a metal sealing ring 120, which is also rectangular. The metal sealing ring is arranged in an external IC functional layer. The sealing ring has an electrically conductive contact on an underside, which contact has an underlying electrically conductive layer 140. The conductive layer 140 can be electrically contacted from the outside via an outer contact surface 121 of the metal sealing ring 120.

FIG. 2B is a schematic plan view and section of the IC chip according to the present invention in a fourth exemplary embodiment. In this case, the etching hole 130 is surrounded directly by the metal sealing ring 120. The metal sealing ring 120 in turn has an electrically conductive contact on an underside, which contact has the underlying electrically conductive layer 140.

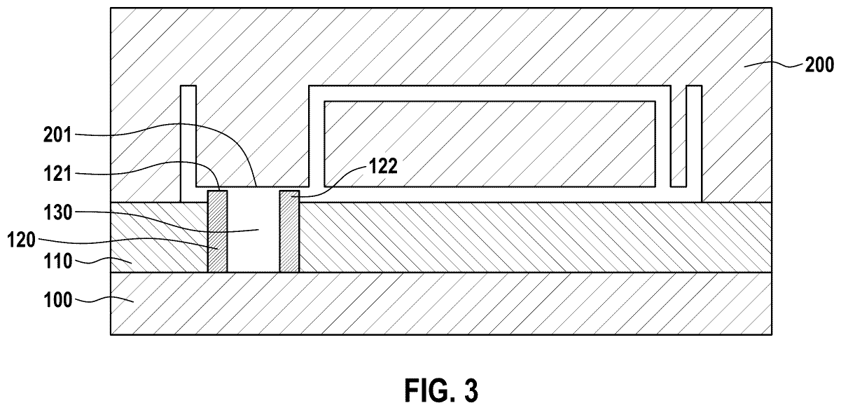

FIG. 3 schematically shows a fifth exemplary embodiment of an IC chip according to the present invention having a metal sealing ring with a flange. Shown is an IC chip having a substrate 100, at least one IC functional layer 110, and a rectangular etching hole 130. In this case, the etching hole 130 is surrounded directly by the metal sealing ring 120. The metal sealing ring 120 does not sit flush with the uppermost IC functional layer 110 of the IC chip, but rather has a raised topography, a flange 122. If the IC chip is bonded to a MEMS chip 200 having a cavity, the metal sealing ring can be used to adjust the distance between the surface 201 of the MEMS chip 200 and the outer contact surface 121 on the upper side of the flange 122 of the metal sealing ring 120.

For example, the distance can be minimized to create regions in the cavity between which gas exchange can take place, but no exchange of particles greater than the distance between the sealing ring and the surface of the MEMS chip. If the etching hole enclosed by the metal sealing ring serves, for example, as an access hole for a trench running through the substrate of the IC chip that is subsequently used for a laser fusion seal, the metal sealing ring having a raised topography can serve an additional function as a bottleneck in the MEMS chip. This allows gas exchange during laser fusion between the external atmosphere and the cavity of the MEMS chip and prevents particles from penetrating the MEMS chip beyond the etching hole through the metal sealing ring.

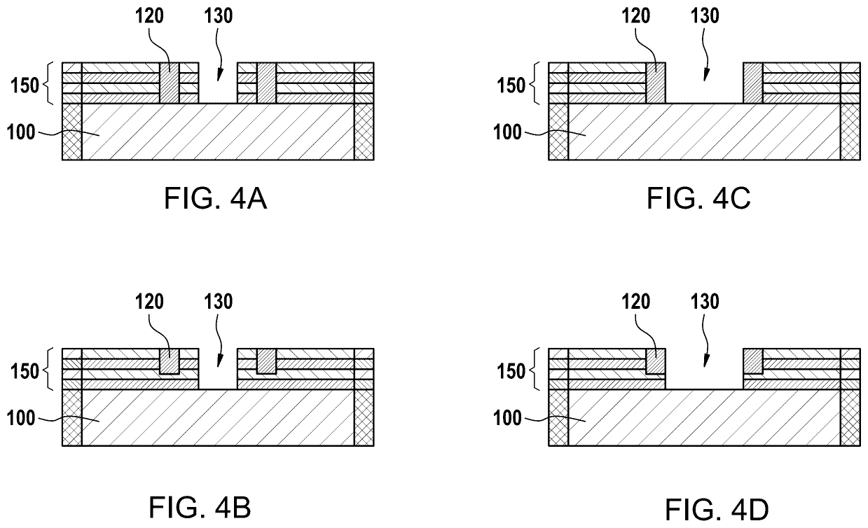

FIGS. 4A and 4D schematically show, in further exemplary embodiments, an IC chip according to the present invention having a metal sealing ring that, in different ways, penetrates an IC functional layer system comprising a plurality of layers, in whole or in part.

In this case, the IC chip has an IC functional layer system 150 comprising a plurality of IC functional layers, and the metal sealing ring 120 can penetrate one, a plurality of, or all functional layers.

FIG. 4A is a schematic sectional view of an IC chip according to the present invention having a substrate 100, an IC functional layer system 150 comprising a plurality of IC functional layers, and an etching hole 130. The etching hole is surrounded directly by a partial region of the IC functional layer system and indirectly by a metal sealing ring 120. The metal seal penetrates the entire IC functional layer system through to the substrate.

FIG. 4B is a schematic sectional view of an IC chip according to the present invention similar to the one in FIG. 4A, but the metal seal 120 only partially penetrates the IC layer system 150. The metal sealing ring therefore does not reach the substrate 100.

FIG. 4C is a schematic sectional view of an IC chip according to the present invention having a substrate 100, an IC functional layer system 150 comprising a plurality of IC functional layers, and an etching hole 130. The etching hole is surrounded directly by a metal sealing ring 120. The metal seal penetrates the entire IC functional layer system through to the substrate.

FIG. 4D is a schematic sectional view of an IC chip according to the present invention similar to the one in FIG. 4C, but the metal seal 120 only partially delimits the IC layer system 150 and the etching hole 130. The metal sealing ring therefore does not reach the substrate 100 and a partial region of the IC layer system directly adjoins the etching hole.

Further embodiments may additionally include a raised topography of the metal seal, for example in the form of a flange as shown in FIG. 3, or an electrically conductive contact, as shown in FIGS. 2A and 2B.

### LIST OF REFERENCE SIGNS

100 IC substrate
110 IC functional layer
111 outer side
120 metal seal
121 outer contact surface of the metal seal
122 flange
130 etching hole
140 electrically conductive layer
150 IC functional layer system comprising a plurality of layers
200 MEMS chip
201 surface of the MEMS chip

What is claimed is:

1. An IC chip, comprising:
an IC substrate;
at least one IC functional layer on the substrate;
an etching hole that penetrates the IC functional layer from an outer side through to the substrate; and
a metal seal is arranged between a region of the IC functional layer and the etching hole.

2. The IC chip according to claim 1, wherein the metal seal surrounds the etching hole as a sealing ring.

3. The IC chip according to claim 1, wherein the metal seal directly delimits the etching hole.

4. The IC chip according to claim 1, wherein the metal seal extends from the outer side through to the substrate.

5. The IC chip according to claim 1, wherein the metal seal is electrically conductively connected to an electrical ground potential of the IC chip.

6. The IC chip according to claim 1, wherein the metal seal has a flange that projects beyond the outer side of the IC functional layer.
